(19) United States
(12) Patent Application Publication
(10) Pub. No.: US 2023/0279536 A1
(43) Pub. Date: Sep. 7, 2023

(54) VAPOR DEPOSITION SOURCE FOR VACUUM VAPOR DEPOSITION APPARATUS

(71) Applicant: ULVAC, INC., Kanagawa (JP)

(72) Inventors: Toshimitsu Nakamura, Kanagawa (JP); Jungo Onoda, Kanagawa (JP)

(73) Assignee: ULVAC, INC., Kanagawa (JP)

(21) Appl. No.: 18/040,675

(22) PCT Filed: Dec. 7, 2021
(86) PCT No.: PCT/JP2021/044812

§ 371 Date: Feb. 6, 2023

(30) Foreign Application Priority Data
Jan. 7, 2021 (JP) 2021-001488

(51) Int. Cl. C23C 14/24

(52) U.S. Cl. CPC C23C 14/243

(57) ABSTRACT

A vapor deposition source for a vacuum vapor deposition apparatus according to the present invention disposed in a vacuum chamber to evaporate a solid vapor deposition material to be vapor-deposited on an object to be subjected to vapor deposition includes: a crucible configured to accommodate the vapor deposition material therein and having a discharge port through which the evaporated vapor deposition material is discharged toward the object to be subjected to vapor deposition; and a heating means configured to heat the vapor deposition material in the crucible. In the crucible, an evaporation facilitator is provided, a partial portion of the evaporation facilitator being immersed in the vapor deposition material liquefied by heating, with a gap between the remaining portion of the evaporation facilitator and an inner surface of the crucible.

### TECHNICAL FIELD

The present invention relates to a vapor deposition source for a vacuum vapor deposition apparatus disposed in a vacuum chamber to vaporize a solid vapor deposition material and vapor-deposit the vaporized material on an object to be subjected to vapor deposition.

### BACKGROUND ART

For example, a process of manufacturing an organic EL element includes a process of depositing a predetermined thin film on a surface of an object to be subjected to vapor deposition such as a substrate in a vacuum atmosphere after evaporating a solid vapor deposition material (organic material) such as α-NPD or 2-TNATA on the object to be subjected to vapor deposition. In such a vapor deposition process, a vacuum vapor deposition apparatus is generally used. A vapor deposition source used in such a vacuum vapor deposition apparatus is known, for example, from Patent Literature 1. The vapor deposition source includes a crucible with an upper side thereof in a vertical direction being opened, and a heating means heating the crucible such as an induction coil (see the section “Related Art”).

In the above-described vapor deposition source as an example of the conventional art, the crucible is filled with, for example, a powdery vapor deposition material, and the crucible is heated by the heating means in a vacuum atmosphere. Then, the vapor deposition material in the crucible is liquefied and then vaporized, but at this time, the vapor deposition material is vaporized only from a liquid surface of the vapor deposition material facing the opening on the upper side of the crucible. For this reason, there is a problem that an evaporated amount per unit time under the same pressure is small, and a rate of vapor deposition on the object to be subjected to vapor deposition is low (that is, productivity is low). In this case, it may be considered to increase a temperature at which the crucible is heated. However, depending on what the vapor deposition material to be used is (organic material), if the heating temperature is increased, the vapor deposition material is decomposed in the vapor deposition source, making it impossible to vapor-deposit a thin film having a desired film quality, that determines the performance of the element. For this reason, it has recently been demanded to develop a vapor deposition source capable of obtaining a high vapor deposition rate as a vapor deposition source of a vacuum vapor deposition apparatus.

### CITATION LIST

### Patent Literature

Patent Literature 1: JP 2010-1529 A

### SUMMARY OF INVENTION

### Technical Problem

In view of the above-described point, an object of the present invention is to provide a vapor deposition source for a vacuum vapor deposition apparatus capable of increasing an evaporated amount of a vapor deposition material per unit time and increasing a rate of vapor deposition on an object to be subjected to vapor deposition when the vapor deposition material is evaporated and vapor-deposited on the object.

### Solution to Problem

In order to solve the above-described problem, a vapor deposition source for a vacuum vapor deposition apparatus according to the present invention disposed in a vacuum chamber to evaporate a solid vapor deposition material to be vapor-deposited on an object to be subjected to vapor deposition includes: a crucible configured to accommodate the vapor deposition material therein and having a discharge port through which the evaporated vapor deposition material is discharged toward the object to be subjected to vapor deposition; and a heating means configured to heat the vapor deposition material in the crucible, wherein an evaporation facilitator is provided in the crucible, a partial portion of the evaporation facilitator being immersed in the vapor deposition material liquefied by heating, with a gap between the remaining portion of the evaporation facilitator and an inner surface of the crucible.

According to the present invention, for example, when a powdery vapor deposition material is filled in the crucible at a predetermined filling rate and the crucible is heated by the heating means in a vacuum atmosphere, the vapor deposition material in the crucible is liquefied. At this time, some of the liquefied vapor deposition material is attracted into the gap between the inner surface of the crucible and a surface of the evaporation facilitator facing the crucible and rises upward due to capillarity. As a result, not only the vapor deposition material liquefied in the crucible can be vaporized from its liquid surface but also the vapor deposition material attracted into the gap can be vaporized, thereby increasing an evaporated amount of the vapor deposition material as compared with that in the example of the conventional art, and accordingly, increasing a rate of vapor deposition on the object to be subjected to vapor deposition. A size of the gap is not particularly limited as long as the capillarity is exhibited, but is set to 100 μm or less, more preferably 60 μm or less. In this case, the gap between the inner surface of the crucible and the surface of the evaporation facilitator facing the crucible does not need to be uniform entirely, and the inner surface of the crucible and the surface of the evaporation facilitator facing the crucible may be, for example, partially in (point) contact with each other. In addition, the evaporation facilitator preferably has a shape not to disturb scattering of what is vaporized from the liquid surface of the vapor deposition material liquefied in the crucible. For example, a plate material itself made of stainless steel or a plate material bent or curved to correspond to an outline of the inner surface of the crucible can be used.

In the present invention, the crucible has a bottomed cylindrical outline with an upper side thereof being open. In addition, the evaporation facilitator is constituted by a mesh member erected on an inner bottom surface of the crucible in a posture to extend in a vertical direction, and it is possible to adopt a configuration in which the liquefied vapor deposition material penetrates into the remaining portion thereof due to capillarity. In this case, the mesh member preferably has an outline corresponding to the inner side surface of the crucible. This makes it possible that, when the vapor deposition material in the crucible is liquefied, the liquefied vapor deposition material also permeates into the remaining portion of the evaporation facilitator exposed to the space in the crucible from the liquefied vapor deposition material by virtue of capillarity. The vapor deposition material penetrating into the remaining portion of the evaporation facilitator is vaporized and scattered from the discharge port toward the object to be subjected to vapor deposition. Therefore, by additionally vaporizing the vapor deposition material from the evaporation facilitator, it is possible to dramatically increase an evaporated amount of the vapor deposition material as compared with that in the example of the conventional art, thereby increasing a rate of vapor deposition on the object to be subjected to vapor deposition.

Here, even in a case where the evaporation facilitator constituted by the mesh member is installed, for example, in a central portion of the crucible in a state where a partial portion of the evaporation facilitator is immersed in the vapor deposition material liquefied by heating, the liquefied vapor deposition material penetrates into the remaining portion of the evaporation facilitator protruding upward from the liquid surface of the vapor deposition material by virtue of capillarity. However, the liquefied vapor deposition material cannot penetrate to a high position of the remaining portion. In addition, in order to effectively vaporize the vapor deposition material having penetrated into the remaining portion of the evaporation facilitator in a vacuum atmosphere, a heating means for heating the remaining portion of the evaporation facilitator may be separately required. On the other hand, in the present invention, since the evaporation facilitator exists in the crucible with a gap between the inner surface of the crucible and the evaporation facilitator, the liquefied vapor deposition material is attracted into the gap and rises upward. As a result, the liquefied vapor deposition material can penetrate to a relatively high position of the remaining portion of the evaporation facilitator. In addition, since the liquefied vapor deposition material is interposed between the inner surface of the crucible and the evaporation facilitator, when the crucible is heated by the heating means, the evaporation facilitator is effectively heated due to heat transfer through the vapor deposition material. Therefore, it is possible to effectively vaporize the vapor deposition material having penetrated into the remaining portion of the evaporation facilitator without an additional heating means. The mesh member may be made of, for example, a material having heat resistance, such as stainless steel (SUS304 or the like), titanium, tantalum, tungsten, molybdenum, or carbon, and formed, for example, by plain-weaving or twill-weaving wire rods having a predetermined diameter, or a plurality sets of twisted wire rods, so that narrow spaces (gaps) are formed between the wire rods.

### BRIEF DESCRIPTION OF DRAWINGS

FIG. 1 is a cross-sectional view schematically illustrating a vacuum vapor deposition apparatus including a vapor deposition source according to an embodiment of the present invention.

FIG. 2 is a partially enlarged cross-sectional view illustrating a state where a vapor deposition material is scattered from the vapor deposition source according to the present invention.

### DESCRIPTION OF EMBODIMENTS

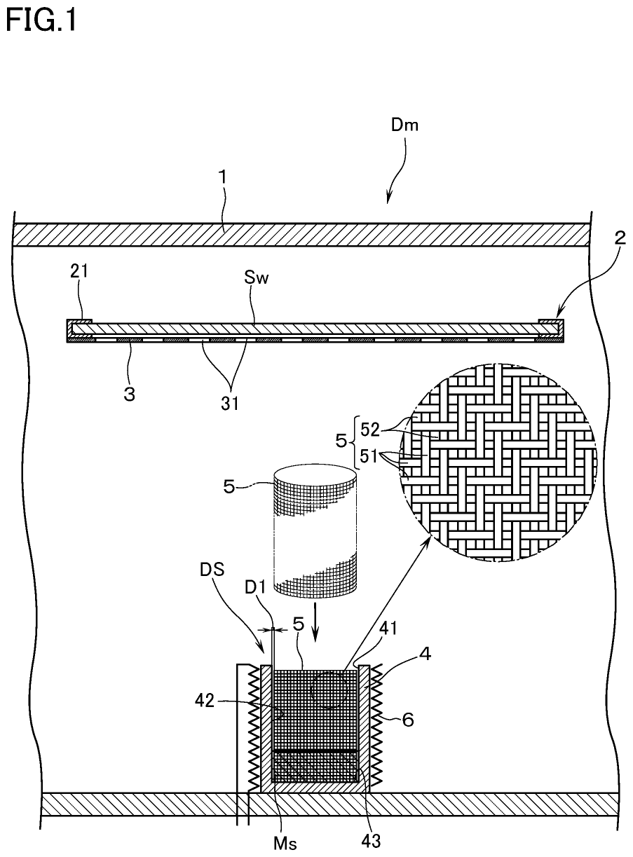

Hereinafter, a vapor deposition source for a vacuum vapor deposition apparatus according to an embodiment of the present invention will be described with reference to the drawings by exemplifying a case where, using a glass substrate having a rectangular outline at a predetermined thickness (hereinafter, referred to as a “substrate Sw”) as an object to be subjected to vapor deposition and a solid organic material Ms that is evaporated by heating (vaporized after becoming a liquid phase) as a vapor deposition material, a predetermined organic film is vapor-deposited on one surface of the substrate Sw. Hereinafter, terms indicating directions such as “upper” and “lower” are used based on FIG. 1, which illustrates an installed posture of the vacuum vapor deposition apparatus.

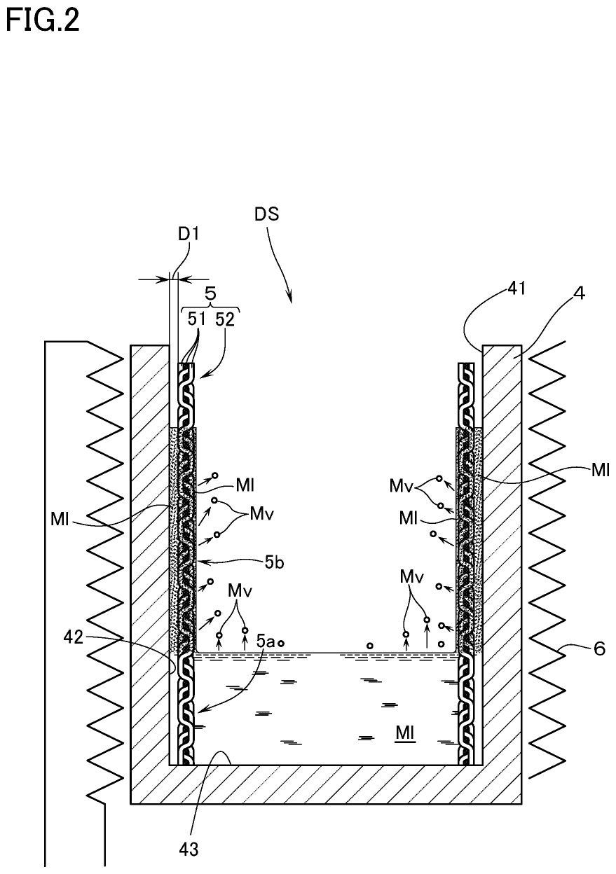

Referring to FIGS. 1 and 2, a vacuum vapor deposition apparatus Dm including a vapor deposition source DS of the present embodiment includes a vacuum chamber 1. Although not particularly illustrated and described, a vacuum pump is connected to the vacuum chamber 1 via an exhaust pipe, such that the vacuum chamber 1 can be evacuated to a predetermined pressure (a degree of vacuum) to form a vacuum atmosphere. In addition, a substrate transfer device 2 is provided in an upper portion of the vacuum chamber 1. The substrate transfer device 2 includes a carrier 21 that holds the substrate Sw in a state where a lower surface thereof is opened as a film forming surface. The substrate transfer device 2 can transfer the carrier 21, and thus the substrate Sw, at a predetermined speed in one direction in the vacuum chamber 1 using a drive device, which is not illustrated. As the substrate transfer device 2, what has been known can be used. Thus, further description thereof will be omitted.

A mask plate 3 having a plate shape is provided between the substrate Sw transferred by the substrate transfer device 2 and the vapor deposition source DS. In the present embodiment, the mask plate 3 is attached integrally to the substrate Sw and is transferred by the substrate transfer device 2 together with the substrate Sw. Note that the mask plate 3 can also be fixedly disposed in the vacuum chamber 1 in advance. The mask plate 3 has a plurality of openings 31 penetrating therethrough in a thickness direction of the plate. Then, the vapor deposition of the evaporated organic material Mv on the substrate Sw is limited at positions where the openings 31 are not provided, such that a film is formed (vapor-deposited) on the substrate Sw in a predetermined pattern. The mask plate 3 is formed using a resin such as polyimide in addition to a metal such as invar, aluminum, or stainless steel, or a metal oxide such as alumina. The vapor deposition source DS of the present embodiment is provided on a bottom surface of the vacuum chamber 1 to face the substrate Sw.

The vapor deposition source DS includes a crucible 4 having a bottomed cylindrical outline with an upper side thereof being open. The crucible 4 is formed of a material having a high melting point (having heat resistance) with excellent thermal conductivity, such as stainless steel (SUS304 or the like), titanium, tantalum, tungsten, molybdenum, or carbon. In the present embodiment, an opening 41 on the upper side of the crucible 4 constitutes a port through which the evaporated vapor deposition material My is discharged. In the crucible 4, a mesh member 5 is provided as an evaporation facilitator with a predetermined gap D1 between an inner side surface 42 of the crucible 4 and the mesh member 5 to enable exhibition of capillarity. The mesh member 5 is made of, for example, a material having heat resistance, such as stainless steel (SUS304 or the like), titanium, tantalum, tungsten, molybdenum, or carbon. Also, the mesh member 5 is formed by twill-weaving (in a range of 150 to 3600 meshes) wire rods 51 each having a predetermined diameter (for example, in a range of Φ0.015 mm to Φ0.45 mm) or a plurality of sets of wire rods 51 twisted to have a predetermined diameter in a sheet shape in such a manner that narrow spaces 52 (gaps) are formed between the wire rods 51 over an entire surface of the mesh member 5, while having an outline corresponding to the inner side surface 42 of the crucible 4 (a cylindrical shape in the present embodiment). In the present embodiment, the mesh member 5 formed in the cylindrical shape is disposed such that an outer surface of the mesh member 5 faces the entire inner side surface 42 of the crucible 4. However, the mesh member 5 is not limited thereto, and the sheet-like mesh member 5 may be curved in an arc shape to partially face the inner side surface 42 of the crucible 4, or a plurality of mesh members 5 curved in this manner may be provided.

A method of installing the mesh member 5 on a lower surface 43 of the crucible 4 is not particularly limited as long as the posture of the mesh member 5 can be maintained even when the solid organic material Ms is liquefied in the crucible 4. For example, a lower end portion of the mesh member 5 may simply be placed in contact with the lower surface 43 of the crucible 4, or the lower end portion of the mesh member 5 may be press-fitted and fixed into a recessed groove (not illustrated) formed in the lower surface 43 of the crucible 4. Meanwhile, a height of the mesh member 5 from the lower surface 43 is not particularly limited as long as, when the solid organic material Ms filled at a predetermined filling rate in the crucible 4 is liquefied, a partial portion (immersed portion 5a) of the mesh member 5 positioned in a lower portion thereof is immersed in the liquefied organic material M1 and the remaining portion (exposed portion 5b) is exposed to a space in the crucible 4 as illustrated in FIG. 2. In the present embodiment, the mesh member 5 is sized so that an upper surface thereof substantially coincides with an upper surface of the crucible 4, and the outer surface of the mesh member 5 entirely faces the inner side surface 42 of the crucible 4 with a predetermined gap D1 therebetween.

A size of the gap D1 is not particularly limited as long as the capillarity is exhibited, but is set to 100 μm or less, more preferably 60 μm or less. In addition, the gap D1 does not need to be uniform entirely, and the outer surface of the mesh member 5 and the inner side surface 42 of the crucible 4 may be partially in (point) contact with each other. For example, depending on what the diameter of the wire rods 51 constituting the mesh member 5 is or how the wire rods 51 are woven, the mesh member 5 may be formed with a plurality of gaps extending in a vertical direction between the wire rods fitted into the crucible 4 and contacting the inner side surface 42 of the crucible 4. In addition, a heating means 6 is provided around the crucible 4 to cover an outer circumferential surface thereof. The heating means 6 is constituted by what has been known such as a sheath heater or a lamp heater. Examples of the organic material Ms used in the vapor deposition source DS for vapor deposition of the present embodiment include α-NPD and 2-TNATA.

When the organic material Ms is vapor-deposited on the substrate Sw using the vapor deposition source DS, the solid organic material Ms is filled in the crucible 4 at a predetermined filling rate in the air atmosphere. Then, when the inside of the vacuum chamber 1 is evacuated and the crucible 4 is heated by the heating means 6, the solid organic material Ms is liquefied due to heat transfer from the crucible 4 as illustrated in FIG. 2. At this time, some of the liquefied organic material M1 is attracted into the gap D1 between the inner side surface 42 of the crucible 4 and the exposed portion 5b of the mesh member 5 and rises upward due to capillarity. In addition, the liquefied vapor deposition material M1 also permeates into the exposed portion 5b of the mesh member 5 due to capillarity. At this time, as rising upward in the gap D1, some of the liquefied organic material Ml exhibits stronger capillarity and penetrates into the exposed portion 5b up to a higher position thereof. Then, the vapor deposition material M1 attracted into the gap D1 and rising upward and the vapor deposition material M1 penetrating into the exposed portion 5b are vaporized and scattered toward the substrate Sw from the opening (discharge port) 41 on the upper side of the crucible 4. As a result, it is possible to dramatically increase an evaporated amount of the vapor deposition material Mv as compared with that in the above-described example of the conventional art, thereby increasing a rate of vapor deposition on the substrate Sw.

As described above, in the present embodiment, since the mesh member 5 is disposed inside the inner side surface 42 of the crucible 4 with the gap D1 interposed therebetween, the liquefied vapor deposition material M1 can penetrate into the exposed portion 5b up to a relatively high position thereof. Moreover, since the liquefied vapor deposition material M1 is interposed between the inner side surface 42 of the crucible 4 and the outer surface of the mesh member 5, when the crucible 4 is heated by the heating means 6, the exposed portion 5b of the mesh member 5 is effectively heated due to heat transfer through the vapor deposition material M1. Therefore, it is possible to effectively vaporize the vapor deposition material M1 that has penetrated into the exposed portion 5b without an additional heating means.

In order to confirm the above-described effect, the following experiment was performed using the vacuum vapor deposition apparatus Dm including the vapor deposition source DS as illustrated in FIGS. 1 and 2. That is, Inventive Product 1 was obtained by forming a sheet-like mesh member 5 to have a cylindrical shape and installing the cylindrical-shape mesh member 5 in a crucible 4 with a gap D1 of 100 μm therebetween, the sheet-like mesh member 5 being formed by twill-weaving wire rods 51 of SUS304 having diameters of Φ0.19 mm and Φ0.13 mm, respectively (400 meshes). Then, in a state where a heating amount per unit time under the same pressure in the vacuum chamber 1 is set to a predetermined value, the vapor deposition material (2-TNATA) Ms filled in the crucible 4 in advance was vapor-deposited. As a result, it was confirmed that a deposition rate (A/s) of about 5 times as high as that in a state where no mesh member 5 was installed under the same conditions (Conventional Product) was obtained. Also, it was confirmed that a relatively high deposition rate was similarly obtained when a-NPD was used as the vapor deposition material Ms.

In addition, Comparative Product was obtained by erecting a sheet-like mesh member 5 at a central portion on the lower surface 43 of the crucible 4, the sheet-like mesh member 5 being formed by twill-weaving wire rods 51 of SUS304 having diameters of Φ0.19 mm and Φ0.13 mm, respectively (400 meshes). Then, as a result of vapor deposition under the same conditions as described above, it was confirmed that the liquefied vapor deposition material M1 in Inventive Product 1 could penetrate into the mesh member 5 to a position from the lower surface of the crucible 4 of about 2.5 times as high as that in Comparative Product. It was also confirmed that even when the pressure in the vacuum chamber 1 was changed at the time of vapor deposition, the height at which the liquefied vapor deposition material M1 penetrated was not changed much. Further, as another experiment, Inventive Product 2 was obtained by forming a plate material of SUS304 having a thickness of 0.5 mm to have a cylindrical shape and installing the cylindrical-shape plate material in a crucible 4 with a gap D1 of 100 μm therebetween. Then, as a result of vapor-depositing a vapor deposition material (2-TNATA) Ms filled in the crucible 4 in advance under the same conditions as described above, it was confirmed that a vapor deposition rate of about 1.5 times as higher as that in Conventional Product was obtained, and the vapor deposition rate could be improved if there is a predetermined gap between a portion of the plate material protruding from the liquefied organic material M1 and an inner surface of the crucible 4.

Although the embodiment of the present invention have been described above, various modifications can be made without departing from the scope of the technical idea of the present invention. In the embodiment described above, the mesh member 5 formed by twill-weaving the wire rods 51 has been described as an example of an evaporation facilitator. However, the evaporation facilitator is not limited thereto as long as the liquefied vapor deposition material M1 can penetrate into the remaining portion 5b exposed to the space in the crucible 4 from the liquefied vapor deposition material M1 by virtue of capillarity. For example, the evaporation facilitator can be formed by plain-weaving the wire rods or stacking two or more sheets of what has been plain-woven. In addition, in the embodiment described above, it has been described as an example that the inner side surface 42 of the crucible 4 is used to install a mesh member 5 formed in a cylindrical shape to correspond to the inner side surface 42. However, the evaporation facilitator is not limited thereto, and for example, a sheet-like mesh member may be installed, for example, by erecting a flat plate made of stainless steel on the lower surface 43 of the crucible 4, with a predetermined gap D1 between the erected flat plate and the inner surface of the crucible 4.

### REFERENCE SIGNS LIST

DS Vapor deposition source for vacuum vapor deposition apparatus

Dm Vacuum vapor deposition apparatus

Ms Organic material (solid vapor deposition material)

M1 Organic material (liquefied vapor deposition material)

Mv Organic material (vaporized deposition material)

Sw Substrate (object to be subjected to vapor deposition)

1 Vacuum chamber

4 Crucible

41 Opening on upper side (discharge port)

42 Inner side surface (inner surface of crucible)

43 Lower surface (inner bottom surface)

D1 Gap (elemental constituent of evaporation facilitator)

5 Mesh member (elemental constituent of evaporation facilitator)

5a Immersed portion (elemental constituent of evaporation facilitator)

5b Exposed portion (remaining portion)

6 Heating means

1. A vapor deposition source for a vacuum vapor deposition apparatus disposed in a vacuum chamber to evaporate a solid vapor deposition material to be vapor-deposited on an object to be subjected to vapor deposition, the vapor deposition source comprising:
a crucible configured to accommodate the vapor deposition material therein and having a discharge port through which the evaporated vapor deposition material is discharged toward the object to be subjected to vapor deposition; and a heating means configured to heat the vapor deposition material in the crucible,
wherein an evaporation facilitator is provided in the crucible, a partial portion of the evaporation facilitator being immersed in the vapor deposition material liquefied by heating, with a gap between the remaining portion of the evaporation facilitator and an inner surface of the crucible.

2. The vapor deposition source for a vacuum vapor deposition apparatus according to claim 1, wherein the crucible has a bottomed cylindrical outline with an upper side thereof being open, and the evaporation facilitator is constituted by a mesh member erected on an inner bottom surface of the crucible in a posture to extend in a vertical direction, such that the liquefied vapor deposition material penetrates into the remaining portion thereof due to capillarity.

3. The vapor deposition source for a vacuum vapor deposition apparatus according to claim 2, wherein the mesh member has an outline corresponding to the inner side surface of the crucible.
